(19) United States
(12) Patent Application Publication
(10) Pub. No.: US 2026/0275552 A1
(43) Pub. Date: Sep. 17, 2026

(54) Cost-efficient operation of a DRI system and of additional sub-systems of an overall system

(71) Applicants: Primetals Technologies Germany GmbH, Erlangen (DE); Primetals Technologies Austria GmbH, Linz (AT)

(72) Inventors: Gerd Becker, Marloffstein (DE); Alexander Fleischanderl, Gruenau (AT); Klaus Weinzierl, Nürnberg (DE)

(21) Appl. No.: 19/471,562

(22) PCT Filed: Apr. 2, 2024
(86) PCT No.: PCT/EP2024/058872

§ 371 Date: Oct. 1, 2025

(30) Foreign Application Priority Data
Apr. 5, 2023 (EP) 23166776.7

(51) Int. Cl. C25B 15/02; C25B 1/02; G06F 30/18

(52) U.S. Cl. CPC C25B 15/02; C25B 1/02; G06F 30/18

(57) ABSTRACT

An overall system that includes, as sub-systems, a DRI system, an electrolysis system, a hydrogen store and a supply device. The DRI system and the electrolysis system are connected to an electricity-supply network for receiving electricity. The DRI system, the electrolysis system and the hydrogen store are interconnected for transferring hydrogen, and the DRI system and the supply device are interconnected for supplying the DRI system with natural gas and/or ammonia. A controller calculates operating modes (B1, B4, B6, B7) for the sub-systems for a forecast horizon (PH) and determines final states (Z1′, Z4′, Z6′, Z7′) that can be expected for the sub-systems on the basis of the current states (Z1, Z4, Z6, Z7) and the operating modes (B1, B4, B6, B7). The controller varies the final states (Z1′, Z4′, Z6′, Z7′) that can be expected so as to minimize a cost function (K).

### TECHNICAL FIELD

The present invention is based on an operating method for an overall system,
wherein the overall system comprises, as subsystems, a DRI installation, an electrolysis installation and a hydrogen storage device,
wherein the DRI installation and the electrolysis installation are connected directly or indirectly to an electrical supply grid in order to draw electrical energy,
wherein the DRI installation, the electrolysis installation and the hydrogen storage device are connected directly or indirectly to one another in order to transfer hydrogen.

The present invention is furthermore based on a control program for a control device for an overall system,
wherein the overall system comprises, as subsystems, a DRI installation, an electrolysis installation and a hydrogen storage device,
wherein the DRI installation and the electrolysis installation are connected directly or indirectly to an electrical supply grid in order to draw electrical energy,
wherein the DRI installation, the electrolysis installation and the hydrogen storage device are connected directly or indirectly to one another in order to transfer hydrogen,
wherein the control program comprises machine code able to be executed by the control device,
wherein the execution of the machine code by the control device causes the control device to control the overall system in line with such an operating method.

The present invention is furthermore based on a control device for an overall system,
wherein the overall system comprises, as subsystems, a DRI installation, an electrolysis installation and a hydrogen storage device,
wherein the DRI installation and the electrolysis installation are connected directly or indirectly to an electrical supply grid in order to draw electrical energy,
wherein the DRI installation, the electrolysis installation and the hydrogen storage device are connected directly or indirectly to one another in order to transfer hydrogen,
wherein the control device is programmed, by way of such a control program, such that the control device, when the machine code of the control program is executed, controls the overall system in line with such an operating method.

The present invention is furthermore based on an overall system,
wherein the overall system comprises, as subsystems, a DRI installation, an electrolysis installation and a hydrogen storage device,
wherein the DRI installation and the electrolysis installation are connected directly or indirectly to an electrical supply grid in order to draw electrical energy,
wherein the DRI installation, the electrolysis installation and the hydrogen storage device are connected directly or indirectly to one another in order to transfer hydrogen,
wherein the overall system comprises such a control device that, when the machine code of such a control program is executed, controls the overall system in line with such an operating method.

### PRIOR ART

The subjects mentioned are known—albeit not specifically for a DRI installation but only for other installations in the steel industry—for example from the article “Grüne Energieversorgung der Stahlindustrie”, Stahl und Eisen, August 2022, pages 22 to 24.

KR 2019 0136300 A discloses an industrial process to which an energy storage device is assigned. The industrial process may be a more or less complex technical process that comprises multiple sub-processes that build on one another and interact with one another. The industrial process has various types of loads, namely loads that must be supplied with energy at all times, loads that are able to be switched off, and loads with a settable energy consumption. The actual energy consumption of the various components of the industrial installation is determined. The operation of the industrial installation and of the energy storage device are coordinated so as to achieve minimal costs.

U.S. Pat. No. 10,354,297 B2 discloses an arrangement comprising a domestic consumer, an energy generator and an energy storage device. The operation of the energy storage device may be ascertained taking into account a planned energy consumption of the consumer. Weather data may furthermore also be used in conjunction. It is also possible to take into account price information for drawing electrical energy from a supply grid and for feeding electrical energy into the supply grid.

TW 201 235 124 A discloses that the energy consumption of a steel industry installation—specific mention is made of a rolling mill—is able to be predicted with good accuracy when the operating mode of the steel industry installation is known.

U.S. Pat. No. 8,288,888 B2 discloses an electrolysis installation coupled to a wind farm. Other loads and other energy sources may additionally be present. The other loads and energy sources may also take the form of electrical energy storage devices. The hydrogen generated by the electrolysis installation may be transferred to an affiliated chemical plant or refinery.

WO 2021/183 022 A1 discloses an operating method for an overall system that comprises, as subsystems, a DRI installation, an electrolysis installation, a hydrogen storage device and a supply device. The DRI installation and the electrolysis installation are connected to an electrical supply grid. Furthermore, the DRI installation, the electrolysis installation and the hydrogen storage device are connected to one another in order to transfer hydrogen, and the DRI installation and the supply device are connected to each other in order to supply a further gas to the DRI installation. The further gas is a synthesis gas that is generated by means of a further electrolysis installation and temporarily stored where necessary.

US 2015/0 259 760 A1 discloses an operating method for an overall system, wherein the overall system comprises, as subsystems, a DRI installation, an electrolysis installation, a hydrogen storage device and a supply device. The DRI installation, the electrolysis installation and the hydrogen storage device are connected directly or indirectly to one another in order to transfer hydrogen. Furthermore, the DRI installation and the supply device are connected to each other in order to supply natural gas and/or ammonia to the DRI installation. The overall system is controlled by predictive control.

### SUMMARY OF THE INVENTION

In the past when ascertaining the operation of steel industry installations, the costs incurred in the process—including the energy costs incurred in the process—were taken into account. This applies equally to DRI installations and other installations in the steel industry. However, they were taken into account only in the sense that the overall electrical energy demand and the resulting electrical energy costs were taken into account. In the course of the shift toward renewable energies, the availability of electrical energy (including the temporal fluctuations of the costs incurred for electrical energy) has to be taken into account to a considerably greater extent, since the availability and thus also the costs of electrical energy will be subject to considerably greater fluctuations in the future than they have been in the past.

However, the cost of operating the overall system is determined by a multiplicity of further factors. The procedures in the prior art are therefore only suboptimal.

Although the abovementioned article explains that the steel industry installation considered there, the electrolysis installation and an electrical energy storage device are controlled and operated by a smart energy management system, it does not contain any more detailed explanations regarding the implementation of the smart energy management system.

The object of the present invention is to provide possibilities that achieve cost-efficient operation of an overall system that comprises, as subsystems, a DRI installation, an electrolysis installation and a hydrogen storage device.

The object is achieved by an operating method having the features of claim 1. Dependent claims 2 to 8 relate to advantageous configurations of the operating method.

First of all, the overall system comprises, as a (further) subsystem, a supply device—in addition to the abovementioned subsystems. The DRI installation and the supply device are connected to each other in order to supply natural gas and/or ammonia to the DRI installation. Furthermore, an operating method of the type mentioned at the outset is configured such that
a control device that controls the overall system is aware, as current states, of a current installation state of the DRI installation, a current electrolysis state of the electrolysis installation, a current hydrogen storage device state of the hydrogen storage device and a current supply state of the supply device,
the control device is aware, for a forecast horizon, of at least a desired production plan of the DRI installation, at least an expected price for electrical energy drawn via the electrical supply grid and at least an expected price for the natural gas and/or ammonia,
the control device sets operating modes for the forecast horizon and ascertains expected final states for the end of the forecast horizon,
the operating modes comprise an installation operating mode for the DRI installation, an electrolysis operating mode for the electrolysis installation, a hydrogen storage device operating mode for the hydrogen storage device and a supply operating mode for the supply device,
the expected final states comprise a final installation state ascertained by exploiting the current installation state and the set installation operating mode, an expected final electrolysis state ascertained by exploiting the current electrolysis state and the set electrolysis operating mode, an expected final hydrogen storage device state ascertained by exploiting the current hydrogen storage device state and the set hydrogen storage device operating mode and an expected final supply state ascertained by exploiting the current supply state and the set supply operating mode,
the control device varies the set operating modes and, based thereon, the expected final states for the forecast horizon so as to minimize a cost function,
the cost function includes the costs of drawing electrical energy from the electrical supply grid, consuming natural gas and/or ammonia and losses of hydrogen stored in the hydrogen storage device and also includes the operating modes of the DRI installation, the electrolysis installation, the hydrogen storage device and the supply device and/or assessments of the expected final conditions and also includes a productivity of the DRI installation, and
the control device operates the subsystems in line with the respective varied operating mode, at least for the beginning of the forecast horizon.

The starting point for the invention is the insight that a DRI installation can alternatively be operated with hydrogen, natural gas or ammonia and that consequently the consumption of natural gas and ammonia and the associated costs and also the costs for the operation of the corresponding supply device can also be included in the optimization.

The supply device may be constructed as required. For example, the supply device, as far as natural gas is concerned, may comprise a tank for the natural gas and/or be connected to a gas supply network. In an alternative to that or in addition, the supply device, as far as ammonia is concerned, may comprise an ammonia generation device. However, this is not absolutely necessary. A storage device for ammonia is also possible.

The installation state of the DRI installation describes the state of the DRI installation to the required extent. For example, the installation state might comprise which materials are in which state at the current time in the DRI installation and the state of units of the DRI installation.

A current electrolysis state of the electrolysis installation may for example, provided there is a corresponding dependency of hydrogen production efficiency on power input, comprise a temperature of the electrolysis installation. The electrolysis state may also comprise other variables that may vary, for example concentrations of electrolytes.

A current hydrogen storage device state describes the state of the hydrogen storage device to the required extent. The hydrogen storage device state may in particular comprise a filling degree or fill level, that is to say the extent (in percentage and/or absolute terms) to which the hydrogen storage device is filled.

The current supply state describes the state of the supply device to the required extent. Insofar as the supply device comprises tanks, the state may for example comprise filling degrees or fill levels of the tanks—analogous to the hydrogen storage device. Optionally, additional data such as maximum fill or withdrawal rates or loss rates or delivery rates may also be defined. The supply state may also comprise a degree of wear of the supply device.

The DRI installation production plan defines the extent to which iron or sponge iron is to be produced by the DRI installation. The production plan may also define which intermediate products are intended to be produced. Furthermore, the production plan may also define planned downtimes of the DRI installation or of parts of the DRI installation. By way of example, a scheduled downtime may be required for maintenance purposes.

The wording that the prices of the electrical energy or natural gas and/or ammonia are “at least expected” comprises, on the one hand, the case that it is an estimate based on known facts. For example, such known facts might be historical data from previous comparable periods or—for electrical energy in particular—a weather forecast. However, it may also relate to a price that is actually known, and so the price is not only expected but also actually given.

The installation operating mode for the DRI installation is somewhat different from the production plan. In particular, the installation operating mode defines, for any time, how the DRI installation is operated (=controlled). The installation operating mode is therefore continuous in terms of time (“the DRI installation is operated in activation state A at 5:52:43 p.m., in activation state B at 5:52:44 p.m., in activation state C at 5:52:45 p.m.” etc.). The installation operating mode must of course be defined such that the specifications of the production plan are met.

The electrolysis operating mode for the electrolysis installation defines, for any time, how the electrolysis installation is operated (=controlled). The electrolysis operating mode is thus continuous in terms of time, in the same way as the installation operating mode. The electrolysis operating mode defines the extent to which power is required by the electrolysis installation and hydrogen is produced by the electrolysis installation.

The DRI installation consumes hydrogen and/or natural gas and/or ammonia. The electrolysis installation produces hydrogen. If no further hydrogen generators and consumers are present other than the DRI installation and the electrolysis installation, the hydrogen storage device operating mode for the hydrogen storage device is a dependent operating mode, because it simply has to receive or output the difference between the hydrogen required by the DRI installation and the hydrogen produced by the electrolysis installation. When determining the installation operating mode and the electrolysis operating mode, it is only necessary to ensure that the hydrogen storage device does not become completely empty, has only a limited capacity and only certain amounts of hydrogen are able to be stored in or removed from the hydrogen storage device per unit of time.

The supply operating mode for the supply device defines in an analogous manner, for any time, how the supply device is operated (=controlled).

The control device ascertains the expected final states for the end of the forecast horizon based on the respective current states by updating them according to the respective operating mode.

Varying the set operating modes with the objective of minimizing the cost function is a typical optimization problem. Optimization problems per se, the way in which optimization problems are addressed and the way in which optimization problems are solved are known to those skilled in the art. Reference may be made, purely by way of example, to
Fletcher, R.: Practical Methods on Optimization. 2^{nd} ed., John Wiley Inc., Chichester, New York 1987,
Hintermuller, M.; Stadler, G.: A semi-smooth Newton methods for linear-quadratic control problems, Zeitschrift für angewandte Mathematik und Mechanik (ZAMM) [Journal of Applied Mathematics and Mechanics]83-4, 219-237, (2003) or
Ito, K.; Kunisch, K.: Semi-smooth Newton methods for state-constrained optimal control problems, Systems and Control Letters, 50, 221-228, (2003).

It is also known from the abovementioned references how it is possible to formulate constraints to be complied with, for example performance limits of the DRI installation. Other matters relevant to the formulation of optimization problems are also known from the abovementioned references. One example of such matters is how deviations from preferred operating states are able to be “penalized”. Another example is how it is possible to formulate conditions to be complied with (through equality secondary constraints). Conditions to be complied with make it possible, for example, to force the state of subsystems of the overall system at the end of the forecast horizon. In the case of the hydrogen storage device, for example, such a state may be its stored amount of hydrogen.

The term “cost function” has a clear-cut meaning for a person skilled in the art in the field of optimization problems. Although it may be understood in the sense of an economic assessment, this is not necessarily the case. In this case, the cost function may incorporate various variables.

Initially, the cost function incorporates the costs of drawing electrical energy from the supply grid. The costs of drawing electrical energy are self-explanatory. It is pointed out merely that the costs may be negative in individual cases, namely when the price of drawing electrical energy becomes negative for a time, for example due to a temporary oversupply. The cost function also incorporates the costs for the consumption of natural gas and/or ammonia. The cost function also incorporates losses of hydrogen contained in the hydrogen storage device (6). The latter takes into account the fact that non-negligible losses occur when hydrogen is stored for a relatively long period of time. Depending on the type of storage, the loss rate is at least 0.1% of the stored amount of hydrogen per day, and may be up to 0.5% per day.

The cost function furthermore incorporates the operating modes of the various subsystems and/or assessments of the expected final states. The assessment of the expected final installation state may comprise wear-induced costs of the DRI installation. The assessment of the expected final installation state may furthermore comprise a component that is ascertained for example by exploiting an energy state or a phase state of products located in the DRI installation. A similar assessment is possible for the electrolysis installation. With regard to the hydrogen storage device and the supply device, the assessment may in particular incorporate a wear. The assessment of the expected final state of the hydrogen storage device may furthermore comprise a component that is ascertained by exploiting a degradation of the hydrogen storage device brought about by the hydrogen storage device operating mode, that is to say a deterioration of the performance of the hydrogen storage device. The same applies to any storage device of the supply device.

The cost function furthermore incorporates a productivity of the DRI installation.

Preferably, the overall system comprises, as a further subsystem, an electrical energy storage device that is directly or indirectly connected to the DRI installation, the electrolysis installation and the electrical supply grid in order to transmit electrical energy. In this case, the control device is aware, as a further current state, of a current storage device state of the electrical energy storage device, and the operating modes set and varied by the control device additionally comprise a storage device operating mode for the electrical energy storage device. Also, the expected final states additionally comprise a final storage device state ascertained by exploiting the current storage device state and the set storage device operating mode. Finally, the control device also varies the storage device operating mode and, based thereon, the expected final storage device state.

The provision of an electrical energy storage device and its incorporation into the optimization considerably improve the flexibility with which it is possible to control the drawing of electrical energy from the supply grid. This is because the—expected—future electrical energy demand of the DRI installation, on the one hand, and the—expected—future price of electrical energy drawn from the supply grid, on the other hand, are crucial for the efficient use of the electrical energy storage device and of the hydrogen storage device in the context of the present invention.

The energy storage device state describes—similar to the other states—the state of the electrical energy storage device to the required extent. The energy storage device state may comprise for example the extent (in percentage and/or absolute terms) to which the energy storage device is charged and the temperature of storage cells of the energy storage device. Furthermore, the energy storage device state may also comprise the state of wear of the energy storage device or parts of the energy storage device. The energy storage device state may furthermore comprise maximum possible operating variables in principle and maximum possible operating variables at the current time, for example charging and discharge currents.

The energy storage device operating mode for the electrical energy storage device defines the extent to which the electrical energy storage device is intended to be charged and discharged, respectively. The energy storage device operating mode is continuous, in the same way as the installation operating mode. An amount of electrical energy taken from the electrical energy storage device may possibly—of course only temporarily—even be so great that it exceeds the energy requirement of the DRI installation and of the electrolysis installation, such that, as a result, electrical energy is fed into the supply grid.

The expected price of electrical energy drawn from the supply grid may be defined in each case individually for different periods. On a spot market, the price is often fixed only for a relatively limited period, for example only 24 hours in advance. Here, specific quantities of energy are traded for fixed periods at a respective spot market price. However, there are also contracts with longer-term commitments, for example a fixed price for a certain performance level for one year in advance. The two examples are of course not the only possible ones.

However, the billing of the actual power draw from the supply grid often deviates from a previously agreed rate, specifically whenever an amount of power different from that purchased beforehand is drawn. By way of example, although the energy draw is purchased from the spot market on an hourly basis, billing is carried out on a quarter-hourly basis. If the amount of energy purchased beforehand is drawn, the agreed rate will also be billed. If, on the other hand, more or less energy is drawn than was purchased beforehand on the spot market, the actual price of electrical energy drawn from the supply grid depends on a number of factors. The actual price incorporates in particular whether and, where applicable, at what expense additionally drawn electrical energy had to be procured by the operator of the supply grid or whether and, where applicable, at what expense electrical energy that was purchased from the operator of the supply grid but not drawn was able to be utilized elsewhere.

In order to be able to reliably ascertain the costs, the forecast horizon is therefore preferably divided into a number of early time periods and a number of late time periods. The number of early and late time periods can be determined as needed. For example, if the purchase is actioned 24 hours in advance and billing is on a quarterly basis, the duration of a single time period is 15 minutes, with the forecast horizon having 96 early and 4 late time periods.

For the early time periods, the control device ascertains the storage device operating mode in such a way that during the early time periods, the overall system draws an amount of electrical energy that is predetermined for the respective early time period from the electrical supply grid. This makes it possible to reliably ascertain the cost of drawing electrical energy in advance for the early time periods. Furthermore, the control device also varies the storage device operating mode, at least for the late time periods, and, based thereon, the expected final storage device state.

The procedure described above shows its full advantages in the case that the control device defines, for the late time periods, quantities of electrical energy that should in each case be drawn from the electrical supply grid during the last periods. As a result, the energy draw purchased for example from a spot market—neither more nor less—is actually needed and drawn even for the late periods of time.

The determination can be made, for example, on the basis of the operating modes of the further subsystems (i.e. without the electrical energy storage device) during the late time periods, a target storage device state of the electrical energy storage device and a deviation of an expected storage device state at the time of transition from the early time periods to the late time periods. In particular, the price of electrical energy can also be incorporated in the determination, and in some cases even additionally the price of the fossil fuel. Optionally, the control device can also actively intervene in pricing, cf. the applicant's patent application filed on the same day as the present application with the German title “Kosteneffizienter Betrieb einer Anlage der Stahlindustrie und weiterer Teilsysteme eines Gesamtsystems”.

Preferably, the control device takes into account a minimum and a maximum charge state of the electrical energy storage device and/or a mean charge state of the electrical energy storage device when varying the operating mode. Taking such variables into account—whether as constraints to be observed or by incorporating them directly into the cost function—makes it possible to achieve a situation whereby the electrical energy storage device has a certain capacity at all times and in both directions—both for receiving electrical energy and for outputting electrical energy—such that it is possible to respond to malfunctions during the operation of the DRI installation and/or the electrolysis in—stallation—where applicable even in the event of malfunctions in the supply grid or other devices—by way of a changed operating mode of the electrical energy storage device.

In some cases, the overall system has, as a further subsystem, a power generation device by way of which electrical energy is able to be generated renewably. In this case, the power generation device is directly or indirectly connected to the DRI installation, the electrolysis installation and the electrical supply grid, usually also to the electrical energy storage device, in order to transmit electrical energy. The power generation device may be designed in particular as a wind turbine or as a photovoltaic installation. The operating method is designed, in the case of an existing power generation device, in such a way that
the control device, for the forecast horizon, is additionally aware of an expected electrical energy able to be generated by the power generation device, and
the control device takes into account the expected electrical energy able to be generated by the power generation device when varying the operating modes.

This enables even further optimization of the operation of the overall system.

Preferably, the control device takes into account a minimum and a maximum fill level of the hydrogen storage device and/or a mean fill level of the hydrogen storage device when varying the operating modes. Taking such variables into account—whether as constraints to be observed or by incorporating them directly into the cost function—makes it possible to achieve a situation whereby the hydrogen storage device has a certain capacity at all times and in both directions—both for receiving hydrogen and for outputting hydrogen—such that it is possible to respond to malfunctions during the operation of the DRI installation and/or the electrolysis installation—where applicable even in the event of malfunctions in the supply grid or other devices—by way of a changed operating mode of the hydrogen storage device.

It may be advantageous if the supply device comprises a generation device for producing ammonia with or without an associated storage device for ammonia. In this case, the generation device is connected directly or indirectly to the DRI installation, the electrolysis installation and the electrical supply grid in order to transmit electrical energy. Furthermore, in this case, the current supply state comprises a current operating state of the generation device, the supply operating mode comprises the operating mode of the generation device and the final expected supply state comprises an expected final operating state of the generation device, wherein the final expected operating state of the generation device is ascertained by the control device by updating the current operating state according to the operating mode of the generation device. Thus, varying the supply operating mode also comprises varying the operating mode of the generation device.

The object is furthermore achieved by a control program having the features of claim 9. According to the invention, the controlled overall system comprises, as a (further) subsystem, a supply device—in addition to the abovementioned subsystems. The DRI installation and the supply device are connected to each other in order to supply natural gas and/or ammonia to the DRI installation. Furthermore, the execution of the machine code by the control device causes the control device to control the overall system in line with an operating method according to the invention.

The object is furthermore achieved by a control device having the features of claim 10. According to the invention, the controlled overall system comprises, as a (further) subsystem, a supply device—in addition to the abovementioned subsystems. The DRI installation and the supply device are connected to each other in order to supply natural gas and/or ammonia to the DRI installation. Furthermore, the control device is programmed, by way of a control program according to the invention, such that the control device, when the machine code of the control program is executed, controls the overall system in line with an operating method according to the invention.

The object is furthermore achieved by an overall system having the features of claim 11. According to the invention, provision is made
for the controlled overall system to comprise, as a (further) subsystem, a supply device—in addition to the abovementioned subsystems,
for the DRI installation and the supply device to be connected to each other in order to supply natural gas and/or ammonia to the DRI installation and
for the control device to be designed as a control device according to the invention, which, when the machine code of the control program is executed, controls the overall system in line with an operating method according to the invention.

### BRIEF DESCRIPTION OF THE FIGURES

The above-described properties, features and advantages of this invention, and the manner in which these are achieved, will become clearer and more clearly comprehensible in conjunction with the following description of one exemplary embodiment, which is explained in more detail in conjunction with the drawings. In the figures:

FIG. 1 shows an overall system,

FIG. 2 shows a flowchart,

FIG. 3 shows a further overall system,

FIG. 4 shows a flowchart,

FIG. 5 shows a timeline,

FIG. 6 shows a flowchart, and

FIG. 7 shows a flow diagram.

### DESCRIPTION OF THE EMBODIMENTS

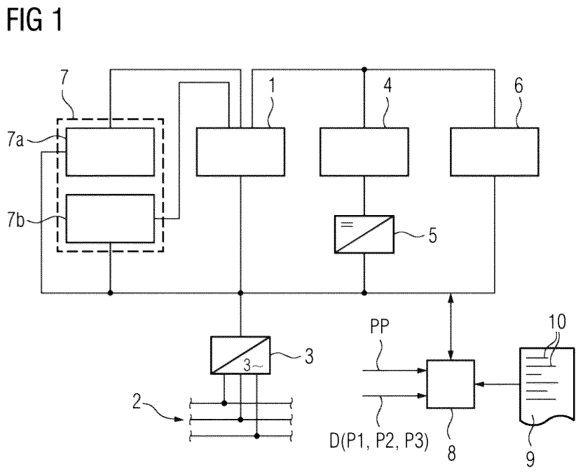

According to FIG. 1, an overall system comprises a DRI (direct reduction of iron) system 1 as a subsystem. In the DRI installation 1, sponge iron is produced from iron ore. The DRI installation 1 requires a constant supply of hydrogen, natural gas and/or ammonia, as well as electrical energy, in accordance with the production.

The DRI installation 1 may draw the electrical energy from an electrical supply grid 2 to which the DRI installation 1 is connected directly (not illustrated) or indirectly (for example via a power converter 3). The supply grid 2 is typically a three-phase grid and thus a multi-phase supply grid. The three-phase grid is often operated with a medium voltage in the range from 20 kV to 30 kV or with a high voltage of 110 kV.

The overall system comprises an electrolysis installation 4 as a further subsystem. The electrolysis installation 4 also consumes electrical energy during operation thereof. The electrolysis installation 4 is therefore likewise connected to the supply grid 2. The electrolysis installation 4 requires a DC voltage to operate. A rectifier 5 is therefore usually arranged upstream of the electrolysis installation 4, and so there is only an indirect connection to the supply grid 2. The DRI installation 1 and the electrolysis installation 4 are connected directly or indirectly to one another in order to transfer hydrogen. Any pumps, valves and the like are not also illustrated in FIG. 1.

The overall system comprises a hydrogen storage device 6 as a further subsystem. The hydrogen storage device 6 may be designed as a storage device in a narrower sense, that is to say as a dedicated hydrogen storage device. However, the pipeline network via which hydrogen is transported also has a certain storage capacity and may serve as a hydrogen storage device 6 for the purposes of the present invention. In the case of a separate dedicated storage device, the storage device may alternatively be arranged overground or underground. The hydrogen storage device 6 is connected directly or indirectly to the electrolysis installation 4 in order to receive hydrogen and connected directly or indirectly to the DRI installation 1 in order to output hydrogen. The operation of the DRI installation 1 and of the electrolysis installation 4 is able to be made more flexible due to the hydrogen storage device 6.

It is possible for the hydrogen generated by the electrolysis installation 4 always to be supplied to the hydrogen storage device 6 and for the hydrogen required by the DRI installation 1 always to be supplied by the hydrogen storage device 6, such that the hydrogen storage device 6 serves as a hydrogen transfer station, as it were. However, a direct connection between the DRI installation 1 and the electrolysis installation 4 is also possible.

The overall system comprises a supply device 7 as a further subsystem. The DRI installation 1 and the supply device 7 are connected to each other in order to supply natural gas and/or ammonia to the DRI installation 1.

FIG. 1 shows a simple configuration of the supply device 7, in which storage devices 7a, 7b are present for storing natural gas and ammonia, respectively. However, alternative configurations are also possible. For example, the supply device 7 may comprise a connection to a supply network for natural gas. In this case, the storage device 7a may—but need not necessarily—be omitted. Likewise, the supply device 7 may comprise a generation device for producing ammonia. In this case, the storage device 7b may—but need not necessarily—be omitted. Furthermore, FIG. 1 shows a configuration of the supply device 7 that is capable of supplying both natural gas and ammonia to the DRI installation 1. However, it is also possible that the supply device 7 of DRI installation 1 is only capable of supplying either natural gas or ammonia.

If the generation device for generating ammonia is comprised, the generation device is generally also connected directly or indirectly to DRI installation 1, electrolysis installation 4 and the electrical supply grid 2 in order to transmit the electrical energy. It is possible that this generation device for the production of ammonia from nitrogen and hydrogen is connected to the electrolysis installation 4 and/or the hydrogen storage device 6.

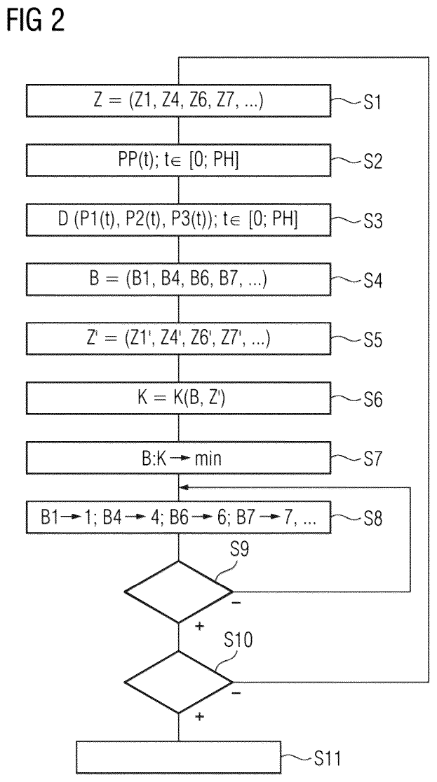

The overall system furthermore comprises a control device 8. The control device 8 is programmed with a control program 9. The control program 9 comprises machine code 10 able to be executed by the control device 8. The programming with the control program 9 causes the control device 8 to execute the machine code 10. The execution of the machine code 10 by the control device 8 causes the control device 8 to control the overall system in line with an operating method that is explained in more detail below in conjunction with FIG. 2. However, even before the operating method according to the invention is explained, it is pointed out that the control device 8 is explained below as being a single control device 8 that jointly controls the subsystems 1, 4, 6 and 7 of the overall system. However, the control device 8 may likewise have its own sub-control device for controlling each of the subsystems 1, 4, 6 and 7. In this case, appropriate information exchange and coordination must take place between the sub-control devices.

In accordance with FIG. 2, in a step S1, the control device 8 is made aware of a current state Z of the overall system. The current state Z comprises a respective current substate Z1, Z4, Z6, Z7 for the subsystems 1, 4, 6 and 7. The number in the respective current substate Z1, Z4, Z6, Z7 corresponds to the reference sign of the respective subsystem 1, 4, 6 and 7.

For example, substate Z1 may comprise the production progress of DRI installation 1. Substate Z1 may furthermore comprise which materials are in which state at the current time in the DRI installation 1.

Substate Z4 may comprise for example a temperature and a chemical composition of the electrolysis fluid of the electrolysis installation 4 and a state of wear of the electrolysis installation 4.

Substate Z6 comprises at least the fill level of the hydrogen storage device 6, that is to say the extent to which the hydrogen storage device 6 is filled. Substate Z6 may also comprise other variables, for example a temperature and/or a gas pressure of the hydrogen storage device 6 or a maximum possible or permissible flow of a hydrogen flow when filling and emptying the hydrogen storage device 6.

Similar explanations may apply to substate Z7 of the supply device 7. If the supply device 7 comprises the generation device for generating ammonia, current supply state Z7 also comprises a current operating state of the generation device.

In a step S2, the control device 8 is made aware of a desired production plan PP of the DRI installation 1. By way of example, the production plan PP may be specified to the control device 8 by an operator (not illustrated). The production plan PP defines which end products are intended to be produced from which starting materials by the DRI installation 1 and which characteristics the end products are intended to have. Generally speaking, the production plan PP also defines which intermediate products are to be produced and by when a specific product is supposed to be produced. The production plan PP extends over a forecast horizon PH. The forecast horizon PH is generally at least several hours, often even in the order of several days.

For example, the production plan PP may include a quantity of pig iron that should be produced per hour or per day using the DRI installation 1. The production plan PP may also specify the minimum amount of carbon that should be contained in the pig iron or sponge iron produced and/or the maximum amount of nitrogen that should be contained in the pig iron or sponge iron produced.

In a step S3, the control device 8 is made aware of data D. The data D are used to determine at least an expected price P1 of electrical energy for the forecast horizon PH, if the electrical energy is drawn from the supply grid 2. The data D are also used to determine at least expected prices P2, P3 for natural gas and/or ammonia. The prices P1 to P3 are defined at least as a function of time t. They may also depend on other circumstances.

If necessary, the control device 8 may initially be made aware of the production plan PP and the data D for the prices P1 to P3 for different time horizons in steps S2 and S3. In this case, the forecast horizon PH is determined by the smallest of the time horizons.

In a step S4, the control device 8 sets an operating mode B for the overall system for the forecast horizon PH. Operating mode B comprises—in the same way as the current state Z—a respective sub-operating mode B1, B4, B6, B7 for the subsystems 1, 4, 6 and 7. The sub-operating modes B1, B4, B6, B7 define, for any time, how the respective subsystem 1, 4, 6, 7 is operated (=controlled). The sub-operating modes B1, B4, B6, B7 may be time-resolved to the second. The set operating modes B, B1, B4, B6, B7 are initially only provisional.

Sub-operating mode B1 for the DRI installation 1—hereinafter also referred to as installation operating mode B1—is defined by the control device 8 such that the specifications of the production plan PP are met. In particular, the installation operating mode B1 may comprise the amounts of materials and energy supplied to DRI installation 1, for example the amount of iron ore, the amount of hydrogen, the amount of natural gas, the amount of ammonia, and the amount of electrical current.

Sub-operating mode B4 for the electrolysis installation 4—hereinafter also referred to as electrolysis operating mode B4—may often be defined separately and relatively flexibly by the control device 8. The control device 8 only has to ensure that the hydrogen requirement of the DRI installation 1 is covered, the filling degree of the hydrogen storage device 6 does not fall below 0% and does not rise above 100% and also that the design limits of the electrolysis installation 4 are observed. As an alternative to a practically free approach for electrolysis operating mode B4, it is also possible to specify, for the electrolysis installation 4 as well, a production plan that must be taken into account when ascertaining electrolysis operating mode B4. As the individual case may be, more or less uniform operation of the electrolysis installation 4 may make sense. However, it may also make sense to vary the operation of the electrolysis installation 4 over time, in particular if electrical energy costs fluctuate greatly.

Sub-operating mode B6 for the hydrogen storage device 6—hereinafter also referred to as hydrogen storage device operating mode B6—is usually no longer able to be defined freely by the control device 8. Rather, it is defined by installation operating mode B1 (and thus the consumption of hydrogen) and electrolysis operating mode B4 (and thus the generation of hydrogen). However, the hydrogen storage device 6 makes it possible, at least to a certain extent, to decouple the operation of the DRI installation 1 and of the electrolysis installation 4 from one another and thus enables flexible operation of the electrolysis installation 4.

Sub-operating mode B7 for the supply device 7—hereinafter also referred to as supply operating mode B7—optionally also comprises the operating mode of the generation device.

In a step S5, the control device ascertains an expected final overall state Z′ for the end of the forecast horizon PH. The expected final overall state Z′ comprises—in the same way as the current state Z—an expected final substate Z1′, Z4′, Z6′, Z7′ for each of the subsystems 1, 4, 6 and 7. The respective expected final substate Z1′, Z4′, Z6′, Z7′ is ascertained by exploiting the respective current substate Z1, Z4, Z6, Z7 and the respective sub-operating mode B1, B4, B6, B7. Specifically, the control device 8 ascertains the respective expected final substate Z1′, Z4′, Z6′, Z7′ by updating the respective current substate Z1, Z4, Z6, Z7 based on the respective sub-operating mode B1, B4, B6, B7. The expected final substate Z7′ optionally also comprises an expected final operating state of the generation device. The expected final operating state is optionally ascertained by the control device 8 by updating the current operating state in line with the operating mode of the generation device.

In a step S6, the control device 8 ascertains the value of a cost function K. The cost function K may incorporate various cost factors. The cost function K is defined as a weighted or unweighted sum of the individual cost factors. For example, cost factors include the cost of drawing electrical energy from the supply grid 2 and of consuming natural gas and/or ammonia. Furthermore, operating modes B1, B4, B6, B7 of subsystems 1, 4, 6, 7 also represent such cost factors. In an alternative to the operating modes B1, b4, B6, B7 of subsystems 1, 4, 6, 7 or in addition to them, evaluations of the expected final states Z1′, Z4′, Z6′, Z7′ are also possible. Finally, the productivity of DRI installation 1 also represents such a cost factor. In addition to the quantity of pig iron or sponge iron produced, the productivity of the DRI installation 1 may also be determined by quality characteristics of the pig iron or sponge iron produced.

To ascertain the costs of drawing electrical energy from the supply grid 2, the control device 8 may for example ascertain the drawing of electrical energy from the supply grid 2 based on the ascertained sub-operating modes B1, B4, B6, B7 and ascertain, based thereon, in conjunction with the known price P1, the associated costs. The ascertainment may take place with the same temporal resolution with which sub-operating modes B1, B4, B6, B7 are also determined, for example to the second. The ascertainment may also take place with a coarser temporal resolution, for example with a resolution of 1 minute or 15 minutes. It is also possible to initially work with a high temporal resolution, for example to the second, but, based thereon, to carry out statistical evaluations for longer periods (for example 1 minute, 5 minutes, 15 minutes), for example to ascertain mean values, maximum values, minimum values, scatter, etc.

Installation operating mode B1 may be assessed for example in terms of productivity, resource-saving operation, an assessment of the wear of the DRI installation 1, etc. Similar assessments are also possible for electrolysis operating mode B4, hydrogen storage device operating mode B6 and supply operating mode B7.

The assessment of the expected final installation state Z1′ may comprise a component that is ascertained for example by exploiting an energy state of the DRI installation 1—this also comprises the energy state of products located in the DRI installation 1. The control device 8 is thereby capable of ascertaining the assessment of the expected final installation state Z1′ taking into account an amount of energy that needs to be applied during subsequent operation of the DRI installation 1 beyond the forecast horizon PH.

The assessment of the expected final installation state Z1′ may also take into account the wear caused by the operation of the DRI installation 1, that is to say the costs resulting from wear that occurs during the production horizon PH due to installation operating mode B1.

The assessment of the expected final electrolysis state Z4′ may likewise comprise a component that is ascertained by exploiting an energy state of electrolysis installation 4, in particular in the case of an electrolysis installation 4 that operates at a high temperature. The assessment may also incorporate concentrations of electrolyte fluids and states of wear.

The assessment of the expected final hydrogen storage device state Z6′ is usually very simple. It is usually just a constant.

The assessment of the expected final supply state Z7′ is usually likewise very simple. Analogously to the final hydrogen storage device state Z6′, it is usually just a constant.

The assessment of the productivity of the DRI installation 1 is usually likewise relatively simple. It is usually better (that is to say the corresponding cost factor is smaller) the greater the quantity of starting product produced in a given unit of time. In the simplest case, the corresponding cost factor is proportional to the time needed to produce a quantity, defined beforehand on a one-off basis, of starting product.

The cost function K also includes costs that take into account the losses of hydrogen in the hydrogen storage device 6. An analogous procedure is optionally also possible for the supply device 7.

The cost function K may also incorporate yet further cost factors. A few possible further cost factors will be discussed below by way of example.

By way of example, it is possible to take into account a cost factor that represents the costs of the remainder of the operation of the DRI installation 1, that is to say the costs that result for the forecast horizon PH in question, but without taking into account the costs of the electrical energy. The costs of the remainder of the operation of the DRI installation 1 may for example comprise the costs of further required input materials (starting materials) or the costs of the preparation of process media or costs due to environmental pollution, for example the costs of carbon taxes.

The cost factor for the remainder of the operation of the DRI installation 1 may furthermore comprise depreciation.

Similarly, it is also possible to take into account cost factors that represent the costs of the remainder of the operation of the electrolysis installation 4 and of the hydrogen storage device 6.

Other costs of the overall system may further also be taken into account if such costs are incurred. Examples of such costs are environmental levies or government subsidies.

The cost function K thus incorporates all free control variables for all subsystems 1, 4, 6, 7. In particular, the quantities of hydrogen and/or natural gas and/or ammonia and the associated costs are also incorporated in cost function K.

In a step S7, the control device 8 solves an optimization problem. The solution to the optimization problem is the combination of those sub-operating modes B1, B4, B6, B7—each considered over the production horizon PH—for which the cost function K as a whole is minimal. The cost function K is thus a functional that is to be minimized and is calculated on the basis of an initial value problem with end conditions. As part of solving the optimization problem, the control device 8 varies the set sub-operating modes B1, B4, B6, B7 for the forecast horizon PH. The variation is carried out taking into account the production plan PP and other constraints, such as for example design limits of the various subsystems 1, 4, 6, 7. This also applies in particular to the operating limits of the supply device 7, for example the possibilities for the production, storage and supply of ammonia. If specified, a production plan of the electrolysis installation 4 is also taken into account as well. Furthermore, when solving the optimization problem, the control device 8 takes into account that the speeds at which the components of hydrogen, natural gas and ammonia supplied to the DRI installation 1 can be changed are limited. The control device 8 thus takes into account that the changes of these components require a certain time. In principle, however, any desired division into hydrogen, natural gas and ammonia is possible. Furthermore, the control device 8 can also take into account that a change in the division into hydrogen, natural gas and ammonia can have an influence on the proportion of carbon in the sponge iron produced by the DRI installation 1 and that subsequent processes are influenced as a result, for example thermally and hence in terms of their energy requirements in particular. It is often advantageous to use a minimum proportion of natural gas. This can be ensured by a corresponding secondary inequality constraint. Given this, varying the supply operating mode B7 also comprises varying the operating mode of the generation device.

When varying the operating modes B1, B4, B6, B7, the control device 10 may additionally also take other conditions into account. Examples of such conditions may be for example specifications for the expected final substates Z1′, Z4′, Z6′, Z7′. By way of example, it is possible to define, as a specification, that the hydrogen storage device 6 has a quite specific filling degree at the end of the forecast horizon PH or the filling degree of the hydrogen storage device 6 lies in a predetermined range at the end of the forecast horizon PH. Similar specifications may optionally also be provided for the supply device 7. Such conditions may be taken into account in particular using what are known as secondary equality constraints and/or secondary inequality constraints. Other conditions are also possible, for example for the energy drawn from the supply grid 2 not to exceed a specified maximum value or for the production of certain products to be complete at a specified time.

Optimization problems per se, their approach and procedures for solving such optimization problems are well known to those skilled in the art. They are also tackled in this way in terms of approach in the abovementioned prior art.

When step S7 is carried out, the varied and thereby optimized sub-operating modes B1, B4, B6, B7 are defined. The control device 8 may therefore, in a step S8, operate the subsystems 1, 4, 6, 7 in line with the varied sub-operating modes B1, B4, B6, B7. This is initially done for the beginning of the forecast horizon PH.

In a step S9, the control device 8 checks whether new information is available thereto. If this is not the case, the control device 8 returns to step S8. When carrying out step S8 again, the control device 8 continues to operate the subsystems 1, 4, 6, 7 in line with the varied sub-operating modes B1, B4, B6, B7. In so doing, it takes into account the progress of time t.

If new information is available to the control device 8, the control device 8 moves to a step 510. In step 510, the control device 8 checks whether the information is a command to stop the operation of the overall system. If this is the case, the control device 8 stops the operation of the overall system in a step 511. Otherwise, the control device 8 returns to step S1. Depending on the type of new information, the control device 8 may alternatively also return to step S2 or to step S3.

As a result, the procedure according to FIG. 2 means that the sub-operating modes B1, B4, B6, B7 continue to be ascertained repeatedly with a certain forecast horizon PH. The ascertainment is thus carried out in the sense of a permanent forecast and is adapted continuously to the expected price P and the production plan PP.

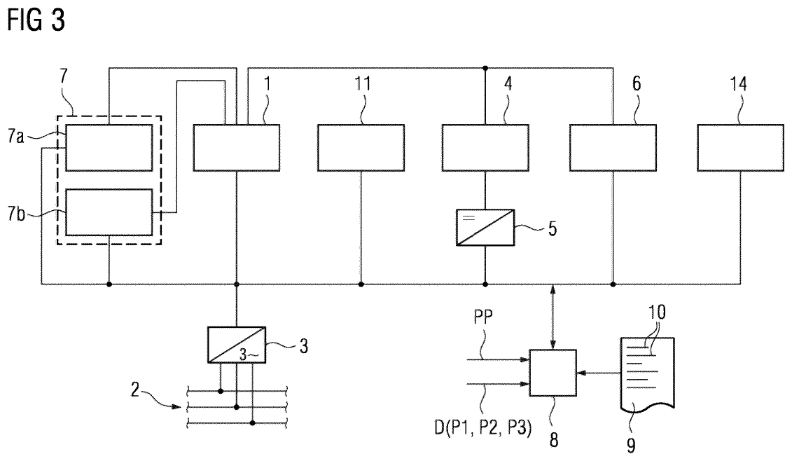

The overall system of FIG. 3 comprises the same components as the overall system of FIG. 1. In addition, however, the overall system comprises an electrical energy storage device 11 as shown in FIG. 3. The energy storage device 11 is connected directly or indirectly to the supply grid 2 at least in order to receive electrical energy, possibly also in order to output electrical energy. The energy storage device 11 is furthermore connected to the DRI installation 1 and to the electrolysis installation 4 in order to output electrical energy. If the energy storage device 11 receives electrical energy, this is always drawn from the supply grid 2. If the energy storage device 11 outputs electrical energy, this is used primarily to cover the demands of the DRI installation 1 and of the electrolysis installation 4 and only secondarily to feed into the supply grid 2. As a result—depending on whether the electrical energy output by the energy storage device 11 is greater or less than the electrical energy consumed by the DRI installation 1 and electrolysis installation 4—electrical energy may thus temporarily be fed into the supply grid 2 or drawn from the supply grid 2.

It must be possible to set whether, and to what extent, electrical energy is supplied to the energy storage device 11 or whether, and to what extent, the electrical energy storage device 11 outputs electrical energy. For this purpose, a bidirectionally operable power converter unit is generally present. This power converter unit is not also illustrated in FIG. 1. Rather, it is considered to be part of the energy storage device 11.

The exact way in which the DRI installation 1, the electrolysis installation 4 and the energy storage device 11 are electrically connected to one another and to the supply grid 2 is of lesser importance. In particular, rectifiers 5, inverters and other power converters 3 may be assigned to the various subsystems 1, 4 and 11, as required. However, it should be ensured that it is possible to transfer electrical energy from the energy storage device 11 to the DRI installation 1 and the electrolysis installation 4 without a diversion via the supply grid 2.

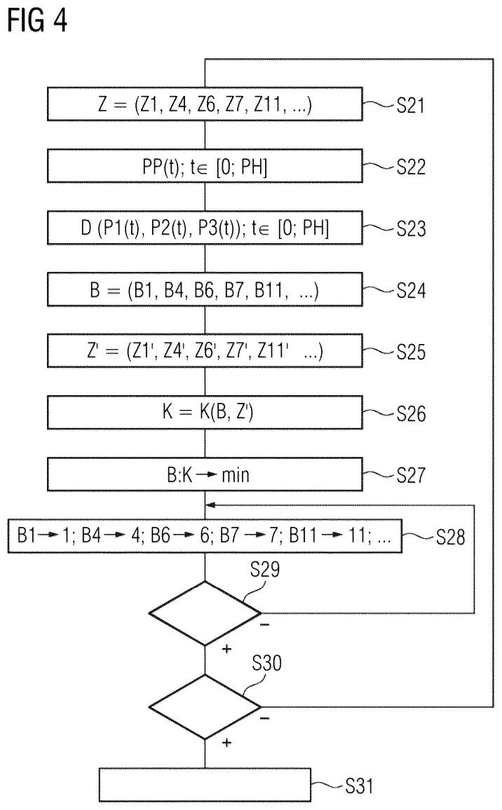

The electrical energy storage device 11 is a further subsystem of the overall system and also treated as such by the control device 8. The integration of the electrical energy storage device 11 into the operating method is shown in FIG. 4.

Steps S21 to S31 of FIG. 4 correspond in terms of approach to steps S1 to S11 of FIG. 2. According to the illustration in FIG. 4, however, the control device 8 is aware of a current storage device state Z11 of the electrical energy storage device 11 as a another current state Z11. Substate Z11 comprises at least the state of charge of the energy storage device 11, that is to say the extent to which the energy storage device 11 is charged. Substate Z11 may also comprise other variables, for example a temperature of the energy storage device 11 or a maximum possible or permissible charging and discharge current. Furthermore, substate Z11 may comprise a state of wear of the energy storage device 11.

For the same reasons, the operating modes set and varied by the control device 8 additionally comprise a storage device operating mode B11 for the electrical energy storage device 11. The sub-operating mode B11 for the energy storage device 11—hereinafter also referred to as energy storage device operating mode B11—may in some cases also be determined independently and relatively flexibly often by the control device 8. The control device 8 only has to ensure that the state of charge of the energy storage device 11 does not fall below 0% and does not rise above 100% and also that the design limits of the energy storage device 11 (for example the maximum charging current and the maximum discharge current) are observed.

Likewise, the expected final states additionally comprise a final storage device state Z11′ ascertained by exploiting the current storage device state Z11 and the set storage device operating mode B11.

Finally, the control device 8 also varies the storage device operating mode B11 within the scope of the optimization and, based thereon, the expected final storage device state Z11′. In doing so, the control device 8 preferably also takes into account a minimum and a maximum state of charge of the electrical energy storage device 11 and/or a mean state of charge of the electrical energy storage device 11 when varying the sub-operating modes B1, B4, B6, B7, B11. This may be taken into account in that deviations from the mean state of charge are incorporated into the cost function K in a manner weighted with an—albeit relatively small—factor and are thus “penalized”. There may also be a requirement for no energy to be fed into the supply grid 2 or for the energy drawn from the supply grid 2 not to exceed a specified maximum value. The assessment of the expected final energy storage device state Z11′ may comprise a component with which the wear caused by the operation of the

energy storage device 11 is taken into account, that is to say the costs resulting from wear that occurs during the production horizon PH due to the storage device operating mode B11.

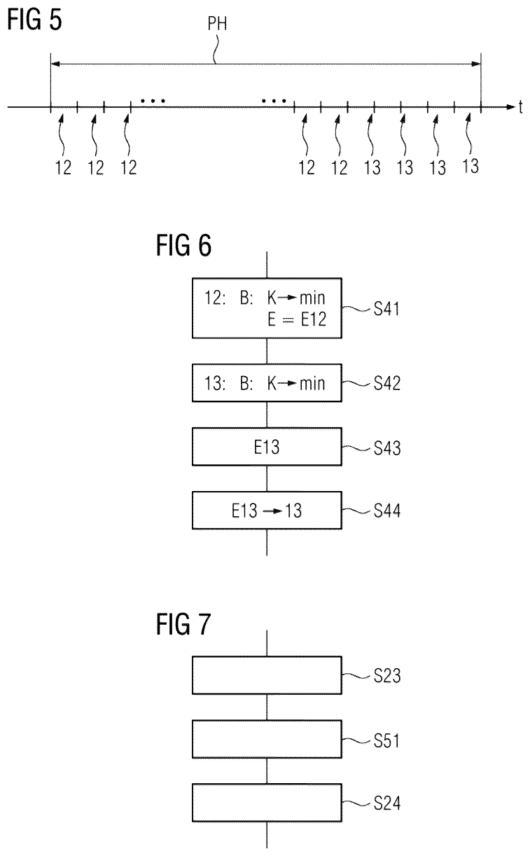

A particularly advantageous configuration of the present invention is explained below in conjunction with FIGS. 5 and 6. The energy storage device 11 is required within the scope of this configuration.

According to FIG. 5, the forecast horizon PH is divided into a number of early time periods 12 and a number of late time periods 13. For example, with a usual forecast horizon PH of 24 hours, the time periods 12, 13 may each have a duration of 15 minutes, and 92 early time periods 12 and 4 late time periods may still be present. However, the duration mentioned and also the numbers mentioned of early and late time periods 12, 13 should be understood as merely purely exemplary in each case.

In the case of a division of the forecast horizon PH into early and late time periods 12, 13, the step S26 of FIG. 4 may be configured in accordance with the illustration in FIG. 6.

According to FIG. 6, step S26 of FIG. 4 is divided into steps S41 and S42. In step S41, the control device 8 optimizes the operating modes B1, B4, B6, B7, B11 for the early time periods 12. In step S42, the control device 8 optimizes the operating modes B1, B4, B6, B7, B11 for the late time periods 13. The difference between steps S41 and S42 consists in the fact that the control device 8 in the optimization during step S41 takes into account the additional boundary condition that during the early time periods 12, the overall system draws a predetermined amount E12 of electrical energy from the electrical supply grid 2 for the respective early time period 12. Although the quantity E12 might be determined on an individual basis for the respective early period 12, it is known. The operating mode B11 of the electrical energy storage device 11 is therefore determined in such a way that the respective amount E of electrical energy drawn from the supply grid 2 during the respective early time period 12 corresponds to this value. By contrast, no such boundary condition is taken into account in step S42. The amount of electrical energy that the overall system draws from the electrical supply grid 2 is thus adjusted during the late time periods 13 in line with the optimization of the operating modes B1, B4, B6, B7, B11. Hence, the control device 8 also varies the storage device operating mode B11 within the scope of the optimization for the late time periods 13 and, based thereon, the expected final storage device state Z11′.

The late time periods 13 are often so far in the future that energy quantities for the late time periods 13 can be firmly ordered on an energy exchange. It is therefore possible to supplement the procedure of FIG. 6 with steps S43 and S44. In step S43, the control device 8 orders quantities of energy for the late time periods 13 on an energy exchange. In step S44, the control device 8 assigns the corresponding amounts of energy to the corresponding late time periods 13, thus for the late time periods 13 determines the corresponding amounts of electrical energy that should be drawn from the electrical supply grid 2 during each of the last time periods 13.

FIG. 3 also shows a further extension of the overall system from FIG. 1. In accordance with FIG. 3, the overall system has a power generation device 14 as a further subsystem. The power generation device 14 may be used to generate electrical energy renewably, that is to say using sunlight or wind power, possibly also using hydropower or geothermal energy. In this case, the power generation device 14 is connected directly or indirectly to the other electrical energy-receiving or outputting subsystems 1, 4, 11, and also to the electrical supply grid 2, in order to transmit electrical energy. A power converter, which is usually required for the power generation device 14, may be considered to be part of the power generation device 14. This is not also illustrated in FIG. 3. Preferably, it is possible to supply electrical energy from the power generation device 14 to the subsystems 1, 4, 11 without a diversion via the supply grid 2.

If the power generation device 14 is present, the procedure of FIG. 4 in accordance with FIG. 7 is initially modified such that a step S51 is additionally present. Step S51 precedes step S24. It can immediately precede step S24 as shown in FIG. 7. However, this is not absolutely necessary. In step S51, the control device 8 is made aware, for the forecast horizon PH, of an amount of electrical energy that is (provisionally) able to be generated by the power generation device 14. Such a forecast may for example be made by utilizing a local weather forecast for the location of the power generation device 14.

Furthermore, the procedure of FIG. 4 is modified such that, in step S26, the expected electrical energy able to be generated by the power generation device 14 is taken into account in the cost function K. This gives rise, in step S27, to other sub-operating modes B1, B4, B6, B7, B11 for which the cost function K becomes minimal.

An explanation is given below, for the DRI installation 1, the electrolysis installation 4 (including the hydrogen storage device 6) and the power generation device 14, of possible models that may be used to ascertain the respective cost factor. These models are implemented within the control device 8 and are evaluated by the control device 8 as part of step S6 or step S26.

For the DRI installation 1, a function v and an electrical setpoint power P* are set, each for the forecast horizon PH. The function v is a function of time t. The setpoint power P* may be a constant. The setpoint power P* is multiplied by the function v. The result is the actual electric power P with which the DRI installation 1 is operated:

$$P = v ( t ) {P}^{*} . \qquad ( 1 )$$

The function v is defined for positive values of time t and has a value range from vmin to 1, wherein vmin itself has a value between 0 and 1. vmin is a function of the state of the DRI installation 1. The current value of vmin takes into account the fact that it is not possible to arbitrarily reduce the actual power P in any state of the DRI installation 1. On the contrary, this depends on the state of the DRI installation 1. The control device 8 therefore has to be aware of the state of the DRI installation 1. As a rule, an attempt will be made to operate the DRI installation 1 as uniformly as possible. The value of vmin will usually only be slightly below 1.

The total electrical energy requirement of the DRI installation 1 is a function of the profile of the function v. It is possible for the control device 8 to ascertain the total electrical energy requirement of the DRI installation 1 independently. As an alternative, the total electrical energy requirement of the DRI installation 1 may for example be specified or ascertained via the energy balance (radiation) of the DRI installation 1.

The function v may be used by the control device 8 to influence the operating mode of the DRI installation 1. Of course, the extent to which the sponge iron is produced is reduced if the function v has a value below 1. The control device 8 can therefore ascertain the associated time delay T and accordingly evaluate:

$$Ka = k 1 + k 2 T . \qquad ( 2 )$$

k1 is a constant with the unit “currency”, for example 2000 euros. k2 is a constant with the unit “currency per time”, for example 1000 euros per minute. T is the time difference by which the production of DRI installation 1 is reduced for the production of a certain amount of sponge iron, for example in minutes.

The cost factor Ka is however confronted by considerable savings potential in terms of energy costs, provided that it manages to shift a high consumption of electrical energy of the DRI installation 1 to times when the electrical energy drawn from the supply grid 2 is inexpensive. Here, the advantages of the present invention are shown, i.e. when the operation of the DRI installation 1, the electrolysis installation 4, the hydrogen storage device 6, the supply device 7 and optionally also the electrical energy storage device 11 are jointly optimized. The advantages may be even greater if power is also able to be generated independently by the power generation device 14.

The cost share Kb caused for the DRI installation 1 due to the supplied electrical energy may be ascertained by integrating the respective instantaneous costs over the production horizon PH. The instantaneous costs may be ascertained as

$$k 3 ( t ) P ( t ) \qquad ( 3 )$$

In this case, k3 is a factor, dependent at least on the time t, which reflects the costs of drawing electrical energy from the supply grid 2.

Similarly, additional cost shares Kc, Kd and Ke caused for the DRI installation 1 due to the supplied hydrogen, natural gas and ammonia may also be ascertained.

Furthermore, direct reduction also produces carbon dioxide, for which certificates are often required when it is released into the environment. This cost share should also be taken into account.

The cost share determined as a whole for the DRI installation 1 is the sum of the cost shares explained above.

The electrolysis installation 4 produces hydrogen and outputs it, and the hydrogen storage device 6 receives hydrogen and outputs it. The fact that stored hydrogen partially escapes is taken into account. As already mentioned, the losses may be up to 0.5% of the stored amount of hydrogen per day. Furthermore, energy is needed to compress the hydrogen under pressure into the hydrogen storage device 6. This energy is usually no longer able to be recovered when the hydrogen is removed from the hydrogen storage device 6. The—common—costs for the operation of the electrolysis installation 4 and of the hydrogen storage device 6 may be ascertained for example by integrating the respective instantaneous costs over the production horizon PH. The instantaneous costs may be ascertained as

$$k 3 ( t ) {P}^{′} ( t ) + k 4 {H}^{′} ( t ) \qquad ( 4 )$$

In this case, k3 is the factor already explained in conjunction with Equation 3. P′ is the electrical energy drawn from the supply grid 2. In the simplest case, the factor k5 is a constant. The factor k5 may also be time-dependent where applicable. H′ is the amount of hydrogen that is currently being lost, that is to say the derivative of the amount of stored hydrogen as a function of time t. If necessary, the wear of the electrolysis installation 4 may also be taken into account as well in the costs.

Similarly, the costs of generating ammonia from hydrogen and storing ammonia, for example, may also be taken into account. It should only also be taken into account that the production of ammonia requires not only energy but also hydrogen. As a rule, the required nitrogen can be extracted from air. However, under certain circumstances costs may be incurred for the separation of oxygen and other gases from the air. Any potential wear of the generation device may also be taken into account.

If the power generation device 14 is assigned directly to the other subsystems 1, 4, 6, 7 and optionally 11, that is to say in particular the electrical energy generated by the power generation device 14 is able to be supplied to the subsystems 1, 4, 6, 7 and optionally 11 without a diversion via the supply grid 2, the generation of the electrical energy is free of charge. If it (temporarily) exceeds the electrical energy consumption of the other subsystems 1, 4, 6, 7 and optionally 11, the electrical energy is fed into the supply grid 2. In this case, in particular, the costs of the power generation device 14 may even be negative.

The present invention has many advantages. In particular, comprehensive optimization of the operation of the overall system consisting of the subsystems 1, 4, 6 and 7, and possibly additionally also the subsystems 11 and 14, is possible.

Although the invention has been illustrated and described more particularly by the preferred exemplary embodiments, the invention is not limited by the examples disclosed and other variations may be derived therefrom by a person skilled in the art without departing from the scope of protection of the invention.

List of reference signs

| | |
|---|---|
| 1 | Installation |
| 2 | Supply grid |
| 3 | Power converter |
| 4 | Electrolysis installation |
| 5 | Rectifier |
| 6 | Hydrogen storage device |
| 7 | Supply device |
| 7a, 7b | Storage devices |
| 8 | Control device |
| 9 | Control program |
| 10 | Machine code |
| 11 | Energy storage device |
| 12, 13 | Time periods |
| 14 | Power generation device |
| B, B1, B4, B6, B7, B11 | Operating modes |
| D | Data |
| E; E12, E13 | Quantities of energy |
| K | Cost function |
| P1 to P3 | Prices |
| PH | Forecast horizon |
| PP | Production plan |
| S1 to S51 | Steps |
| t | Time |
| Z, Z1, Z4, Z6, Z7, Z11 | Current states |
| Z′, Z1′, Z4′, Z6′, | Expected final states |
| Z7′, Z11′ | |

1. An operating method for an overall system,
wherein the overall system comprises, as subsystems, a DRI installation, an electrolysis installation, a hydrogen storage device and a supply device,
wherein the DRI installation and the electrolysis installation are connected directly or indirectly to an electrical supply grid in order to draw electrical energy,
wherein the DRI installation, the electrolysis installation and the hydrogen storage device are connected directly or indirectly to one another in order to transfer hydrogen,
wherein the DRI installation and the supply device are connected to each other in order to supply natural gas and/or ammonia to the DRI installation,
wherein a control device that controls the overall system is aware, as current states, of a current installation state (Z1) of the DRI installation, a current electrolysis state (Z4) of the electrolysis installation, a current hydrogen storage device state (Z6) of the hydrogen storage device, and a current supply state (Z7) of the supply device,
wherein the control device is aware, for a forecast horizon (PH), of at least a desired production plan (PP) of the DRI installation, at least an expected price (P1) for electrical energy drawn via the electrical supply grid and at least an expected price (P2, P3) for the natural gas and/or ammonia,
wherein the control device sets operating modes (B1, B4, B6, B7) for the forecast horizon and ascertains expected final states (Z1′, Z4′, Z6′, Z7′) for the end of the forecast horizon (PH),
wherein the operating modes (B1, B4, B6, B7) comprise an installation operating mode (B1) for the DRI installation, an electrolysis operating mode (B4) for the electrolysis installation a hydrogen storage device operating mode (B6) for the hydrogen storage device (6) and a supply operating mode (B7) for the supply device,
wherein the expected final states (Z1′, Z4′, Z6′, Z7′) comprise a final installation state (Z1′) ascertained by exploiting the current installation state (Z1) and the set installation operating mode (B1), an expected final electrolysis state (Z4′) ascertained by exploiting the current electrolysis state (Z4) and the set electrolysis operating mode (B4), an expected final hydrogen storage device state (B6′) ascertained by exploiting the current hydrogen storage device state (Z6) and the set hydrogen storage device operating mode (B6) and an expected final supply state (Z7′) ascertained by exploiting the current supply state (Z7) and the set supply operating mode (B7),
wherein the control device varies the set operating modes (B1, B4, B6, B7) and, based thereon, the expected final states (Z1′, Z4′, Z6′, Z7′) for the forecast horizon (PH) so as to minimize a cost function (K),
wherein the cost function (K) includes the costs of drawing electrical energy from the electrical supply grid, consuming natural gas and/or ammonia and losses of hydrogen stored in the hydrogen storage device and also includes the operating modes (B1, B4, B6, B7) of the DRI installation, the electrolysis installation, the hydrogen storage device), and the supply device and/or assessments of the expected final conditions (Z1′, Z4′, Z6′, Z7′) and also a productivity of the DRI installation, and
wherein the control device operates the subsystems in line with the respective varied operating mode (B1, B4, B6, B7), at least for the beginning of the forecast horizon (PH).

2. The operating method as claimed in claim 1, where
the overall system comprises an electrical energy storage device as a further subsystem,
the electrical energy storage device is connected directly or indirectly to the DRI installation, the electrolysis installation and the electrical supply grid in order to transmit electrical energy,
the control device is aware, as a further current state (Z11), of a current storage device state (Z11) of the electrical energy storage device, and the operating modes set and varied by the control device additionally comprise a storage device operating mode (B11) for the electrical energy storage device,
the expected final states additionally comprise a final storage device state (Z11′) ascertained by exploiting the current storage device state (Z11) and the set storage device operating mode (B11), and
the control device also varies the storage device operating mode (B11) and, based thereon, the expected final storage device state (Z11′).

3. The operating method as claimed in claim 2, wherein
the forecast horizon (PH) is divided into a number of early time periods and a number of late time periods,
the control device ascertains the storage device operating mode (B11) for the early time periods, in such a way that during the early time periods, the overall system draws an amount of electrical energy (E12) that is predetermined for the respective early time period from the electrical supply grid, and
in that the control device also varies the storage device operating mode (B11) at least for the late time periods and, based thereon, the expected final storage device state (Z11′).

4. The operating method as claimed in claim 3, wherein
for the late time periods, the control device determines amounts (E13) of electrical energy that should be drawn from the electrical supply grid during each of the last time periods.

5. The operating method as claimed in claim 2, wherein
the control device takes into account a minimum and a maximum state of charge of the electrical energy storage device and/or a mean state of charge of the electrical energy storage device when varying the operating modes (B1, B4, B6, B7, B11).

6. The operating method as claimed in claim 1, wherein
the overall system has, as a further subsystem, a power generation device by way of which electrical energy is able to be generated renewably,
the power generation device is connected directly or indirectly to the DRI installation, the electrolysis installation and the electrical supply grid in order to transmit electrical energy,
the control device, for the forecast horizon (PH), is additionally aware of an expected electrical energy able to be generated by the power generation device, and
the control device takes into account the expected electrical energy able to be generated by the power generation device when varying the operating modes (B1, B4, B6, B7).

7. The operating method as claimed in claim 1, wherein
the control device takes into account a minimum and a maximum fill level of the hydrogen storage device and/or a mean fill level of the hydrogen storage device when varying the operating modes (B1, P4, B6, B7).

8. The operating method as claimed in claim 1,
the supply device comprises a generation device for generating ammonia, with or without an associated storage device for ammonia,
the generation device is connected directly or indirectly to the DRI installation, the electrolysis installation and the electrical supply grid in order to transmit electrical energy,
the current supply state (Z7) comprises a current operating state of the generation device,
the supply operating mode (B7) comprises the operating mode of the generation device,
the final expected supply state (Z7′) comprises an expected final operating state of the generation device, which is ascertained by the control device by updating the current operating state in line with the operating mode of the generation device, and
varying the supply operating mode (B7) also comprises varying the operating mode of the generation device.

9. A control program for a control device (8) for an overall system,
wherein the overall system comprises, as subsystems, a DRI installation, an electrolysis installation, a hydrogen storage device and a supply device,
wherein the DRI installation and the electrolysis installation are connected directly or indirectly to an electrical supply grid in order to draw electrical energy,
wherein the DRI installation, the electrolysis installation and the hydrogen storage device are connected directly or indirectly to one another in order to transfer hydrogen,
wherein the DRI installation and the supply device are connected to each other in order to supply natural gas and/or ammonia to the DRI installation,
wherein the control program comprises machine code able to be executed by the control device,
wherein the execution of the machine code by the control device causes the control device to control the overall system in line with an operating method as claimed in claim 1.

10. A control device for an overall system,
wherein the overall system comprises, as subsystems, a DRI installation, an electrolysis installation, a hydrogen storage devices and a supply device,
wherein the DRI installation and the electrolysis installation are connected directly or indirectly to an electrical supply grid in order to draw electrical energy,
wherein the DRI installation, the electrolysis installation and the hydrogen storage device are connected directly or indirectly to one another in order to transfer hydrogen,
wherein the DRI installation and the supply device are connected to each other in order to supply natural gas and/or ammonia to the DRI installation,
wherein the control device is programmed control the overall system in line with an operating method as claimed in claim 1.

11. An overall system,
wherein the overall system comprises, as subsystems, a DRI installation, an electrolysis installation, a hydrogen storage device and a supply device,
wherein the DRI installation and the electrolysis installation are connected directly or indirectly to an electrical supply grid in order to draw electrical energy,
wherein the DRI installation, the electrolysis installation and the hydrogen storage device are connected directly or indirectly to one another in order to transfer hydrogen,
wherein the DRI installation and the supply device are connected to each other in order to supply natural gas and/or ammonia to the DRI installation,
wherein the overall system comprises a control device controls the overall system in line with an operating method as claimed in claim 1.
